(19) United States
(12) Patent Application Publication
(10) Pub. No.: US 2012/0281477 A1
(43) Pub. Date: Nov. 8, 2012

(54) SEMICONDUCTOR MEMORY DEVICE

(76) Inventors: Manabu Sakaniwa, Yokohama-shi (JP); Koki Ueno, Yokohama-shi (JP); Shigefumi Irieda, Yokohama-shi (JP); Eietsu Takahashi, Yokohama-shi (JP); Yasuhiro Shiino, Yokohama-shi (JP); Daisuke Kouno, Yokkaichi-shi (JP)

(21) Appl. No.: 13/308,736

(22) Filed: Dec. 1, 2011

(30) Foreign Application Priority Data
May 2, 2011 (JP) 2011-103215

(51) Int. Cl. G11C 16/26

(52) U.S. Cl. 365/185.18

(57) ABSTRACT

According to one embodiment, a semiconductor memory device includes a memory cell array includes a plurality of cell units each composed of a plurality of memory cells which are arranged at intersections of a plurality of bit lines and a plurality of word lines and whose current paths are connected in series and select transistors each connected to either end of the series connection, a voltage generator circuit which generates a voltage applied to the memory cell array, and a control circuit which controls the memory cell array and the voltage generator circuit.

### CROSS-REFERENCE TO RELATED APPLICATIONS

This application is based upon and claims the benefit of priority from prior Japanese Patent Application No. 2011-103215, filed May 2, 2011, the entire contents of which are incorporated herein by reference.

### FIELD

Embodiments described herein relate generally to a semiconductor memory device.

### BACKGROUND

Of semiconductor memory devices, for example, a NAND flash memory comprises NAND cell units in each of which a plurality of current paths of memory cells are connected in series.

When data is read, a read pass voltage (VREAD) is applied to the unselected cells in the NAND cell units to form channels and a read voltage (AR) is applied to the selected cell, thereby reading the threshold value of the selected cell.

### BRIEF DESCRIPTION OF THE DRAWINGS

FIG. 1 is a block diagram showing an overall configuration of a semiconductor memory device according to a first embodiment;

FIG. 2 is a sectional view to explain voltage relations when data is read in the semiconductor memory device according to the first embodiment;

FIG. 3 is a timing chart to explain a data read operation in the semiconductor memory device of the first embodiment;

FIG. 4 shows the inclination of the rising of the voltage of an unselected word line and that of the rising of the voltage of a select gate line when data is read in the semiconductor memory device of the first embodiment;

FIG. 5 shows an example of generating voltage waveforms in the semiconductor memory device of the first embodiment;

FIG. 6 shows the inclination of the rising of the voltage of an unselected word line and that of the rising of the voltage of a word line adjacent to the selected word line when data is read in the semiconductor memory device of the first embodiment;

FIG. 7 is a diagram to explain the number of failure bits after data is read in the semiconductor memory device of the first embodiment;

FIG. 8 shows the inclination of the rising of the voltage of an unselected word line and that of the rising of the voltage of a word line adjacent to the selected word line when data is read in a semiconductor memory device according to a second embodiment;

FIG. 9 shows the inclination of the rising of the voltage of an unselected word line when data is read in the semiconductor memory device of the second embodiment;

FIG. 10A shows voltage relations when data is written into a NAND cell unit;

FIG. 10B shows the inclination of the rising of the voltage of each of the selected word line and an unselected word line when data is read in a semiconductor memory device according to a third embodiment;

FIG. 11 shows the inclination of the rising of the voltage of each of the selected word line and an unselected word line when data is read in a semiconductor memory device according to a fourth embodiment;

FIG. 12 shows the inclination of the rising of the voltage of an unselected word line and that of the rising of the voltage of a word line adjacent to the selected word line when data is read in a semiconductor memory device according to a fifth embodiment; and

FIG. 13 shows the inclination of the rising of the voltage of an unselected word line and that of the rising of the voltage of a word line adjacent to the selected word line when data is read in a semiconductor memory device according to a sixth embodiment.

### DETAILED DESCRIPTION

In general, according to one embodiment, a semiconductor memory device includes a memory cell array comprising a plurality of cell units each composed of a plurality of memory cells which are arranged at intersections of a plurality of bit lines and a plurality of word lines and whose current paths are connected in series and select transistors each connected to either end of the series connection, a voltage generator circuit which generates a voltage applied to the memory cell array, and a control circuit which controls the memory cell array and the voltage generator circuit. The control circuit, when reading data from a memory cell, performs control so as to cause a voltage applied to unselected word lines in the cell units to have a first inclination until a first read pass voltage has been reached smaller than an inclination until a select voltage of the select transistor has been reached and so as to raise the unselected word lines in voltage later than the select voltage.

As described above, when data is read from a NAND flash memory, a read pass voltage (VREAD) is applied to the unselected cells in the NAND cell units to form channels and a read voltage (AR) is applied to the selected cell, thereby reading the threshold value of the selected cell.

However, a read stress increases due to the magnitude and duration of a read pulse (VREAD) applied to the unselected cells, which might cause read disturbances.

Hereinafter, concrete embodiments will be explained with reference to the accompanying drawings. While in the explanation, a NAND flash memory is used as an example of a semiconductor memory device, this is illustrative and not restrictive. In the explanation, like parts throughout the drawings are indicated by the same reference numerals.

### First Embodiment

<1. Overall Configuration>

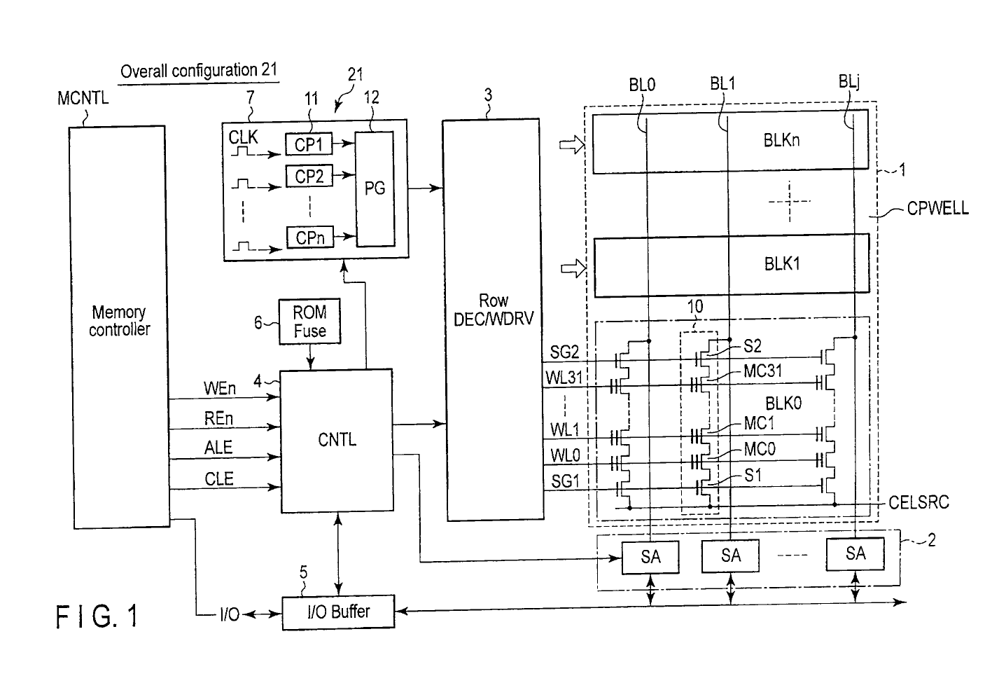

An overall configuration of a semiconductor memory device according to a first embodiment will be explained with reference to FIG. 1.

As shown in FIG. 1, a NAND flash memory 21 of the first embodiment comprises a memory cell array 1, a sense amplifier circuit 2, a row decoder 3, a controller 4, an input/output buffer 5, a ROM fuse 6, and a voltage generator circuit 7. The controller 4 constitutes a control module for the memory cell array 1.

The memory cell array 1 is composed of a plurality of blocks (BLK0, BLK1, . . . BLKn) in each of which NAND cell units 10 are arranged in a matrix. A NAND cell unit 10 is composed of memory cells MCs (MC0, MC1, . . . , MC31) whose current paths are connected in series and select gate transistors S1, S2 each connected to either end of the series connection of the memory cells MCs.

Although not shown, a memory cell MC has a floating gate electrode acting as a charge storage layer on a gate insulating film (tunnel insulating film) formed between a drain and a source, with a control gate electrode formed above the floating gate electrode via an inter-gate insulating film. The control gate is connected to one of the word lines.

The source of the select gate transistor S1 is connected to a common source line CELSRC and the drain of the select gate transistor S2 is connected to a bit line BL.

The control gates of the memory cells MCs in a NAND cell unit 10 are connected to different word lines WLs (WL0, WL1, . . . , WL31) in a one-to-one correspondence. The gates of the select gate transistors S1, S2 are connected to select gate lines SG1, SG2 in parallel with word lines WL. A set of memory cells 10 sharing a word line constitutes one page or two pages. A set of NAND cell units sharing word lines WL and select gate lines SG1, SG2 constitutes a block BLK serving as a unit of data erasing. The memory cell array 1 including a plurality of blocks (BLK0, BLK1, . . . , BLKn) is formed in a cell well (CPWELL) of a silicon substrate.

The sense amplifier circuit (SA) 2 is connected electrically to bit lines BL of the memory cell array 1. The sense amplifier circuit 2 comprises a plurality of sense amplifiers SA constituting a page buffer for sensing read data and holding write data. The sense amplifier circuit 2 includes column select gates.

The row decoder (including a word line driver) (RowDED/WDRV) 3 selects a word line WL and select gate lines SG1, SG2 and drives them.

The controller (CNTL) 4 receives external control signals, including a write enable signal WEn, a read enable signal REn, an address latch enable signal ALE, and a command latch enable signal CLE, and controls an overall operation of the NAND flash memory 21. These signals are sent form a memory controller MCNTL.

Specifically, the controller 4, which includes a command interface and an address holding and transfer circuit, determines whether the supplied data is write data or address data. Depending on the determination result, the write data is transferred to the sense amplifier circuit 2 and the address data is transferred to the row decoder 3 and sense amplifier circuit 2. In addition, on the basis of an external control signal, the controller 4 performs sequence control of data reading, data writing, and data erasing and control of applied voltages.

The data input/output buffer (I/O Buffer) 5 not only performs the exchange of data between the sense amplifier circuit 2 and external input/output terminals but also receives command data and address data. These signals are sent form a memory controller MCNTL, too.

In the ROM fuse 6, for example, parameters and others related to read voltage levels used in a data read operation are recorded. They are read from, for example, the ROM fuse 6 when the power supply of the NAND flash memory 21 is turned on and loaded into a register circuit (not shown) in the controller 4. They are used when, for example, the NAND flash memory 21 operates.

The voltage generator circuit 7 comprises step-up circuits 11 and a pulse generator circuit 12. Each of the step-up circuits 11 is composed of a plurality of charge pump circuits (CP1, CP2, . . . , CPn). Each step-up circuit 11 charges a specific voltage according to a clock CLK supplied by a clock generator circuit (not shown) and outputs the voltage to the pulse generator circuit. The pulse generator circuit (PG) 12 generates a desired pulse voltage necessary for data read operations according to the input from the step-up circuits 11.

With this configuration, the voltage generator circuit 7 changes the number of clocks in an input clock CLK and the number of step-up circuits 11 to be driven according to a control signal from the controller 4 and controls the pulse generator circuit 12, thereby generating a desired pulse voltage. The reason why the number of clocks in the clock CLK and the number of step-up circuits 11 to be driven are changed is to change the rise time of a pulse voltage (or the degree of dullness of the inclination of a voltage waveform) as described later.

<2. Data Read Operation>

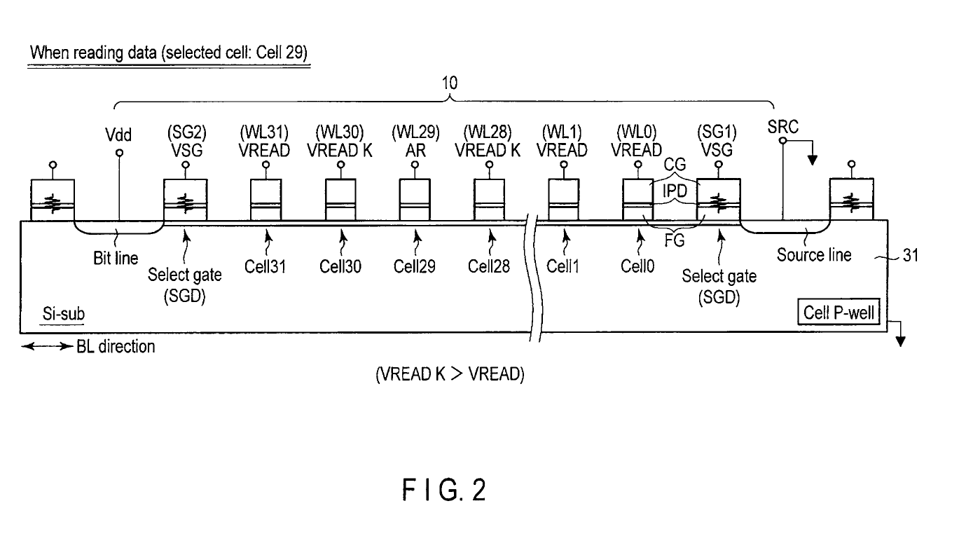

Next, a data read operation in the semiconductor memory device of the first embodiment will be explained with reference to FIGS. 2 to 5.

2-1. Voltage Relations in a Data Read Operation

FIG. 2 shows voltage relations when data is read in a NAND cell unit 10. As shown in FIG. 2, each of memory cells MC0 to MC31 and select gates SGS, SGD comprises a tunnel insulating film, a floating electrode FG, an inter-gate insulating film IPD, and a control gate CG which are provided sequentially on a well of the semiconductor substrate. An opening is made in the central part of the inter-gate insulating film IPD of each of the select gates SGS, SGD, thereby causing the floating electrode FG and control electrode CG to be electrically connected to each other.

With this configuration, the voltage relations in a data read operation are as follows. A case where the selected cell is assumed to be memory cell MC29 is taken as an example.

A read voltage AR is applied to the selected word line WL29 of the selected cell MC29.

A read pass voltage VREAD is applied to unselected word lines WL0 to WL27 and WL31 of the unselected cells MC0 to MC27 and MC31. The read pass voltage VREAD is applied, forming the channels of the unselected cells MC0 to MC27 and MC31, which causes a current path to conduct.

A voltage VREADK higher than the read pass voltage is applied to word liens WL28, WL30 adjacent to the selected cell MC29 (VREADK>VREAD).

A select voltage VSG is applied to select gates SGS, SGD.

An internal power supply voltage Vdd is applied to a bit line.

A source voltage SRC is applied to a source line.

A specific well voltage is applied to a well (Cell P-well) in the semiconductor substrate.

2-2. Timing Chart for a Data Read Operation

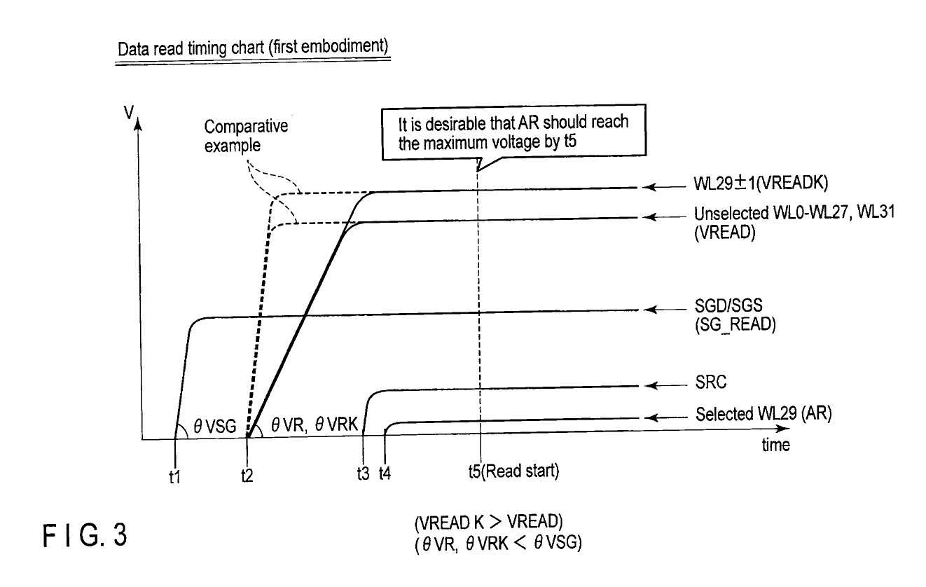

Next, a data read operation will be explained in more detail with reference to the timing chart of FIG. 3. In this operation, overall control is performed by the controller 4.

First, at time t1, a select voltage (SG_READ (VSG)) is applied to select gates SGS, SGD. The rising of the select voltage (SG_READ(VSG)) has an inclination of θVSG. This will be explained in detail later.

Then, at time t2, the read pass voltage VREAD is applied to the unselected word lines WL0 to WL27 and WL31 and a voltage VREADK higher than the read pass voltage is applied to word lines WL28, WL39 adjacent to the selected word line WL29. The rising of the read pass voltage VREAD has an inclination of θVR and the rising of the voltage VREADK has an inclination of θVRK. This will be described in detail later. The inclinations θVR, θVRK are smaller than the inclination θVSG of the select voltage (θVR, θVRK<θVSG).

The voltage VREADK applied to word lines WL28, WL30 adjacent to the selected word line WL29 is stepped up until it becomes higher than the read pass voltage VREAD (VREADK>VREAD).

Then, at time t3, a source voltage SRC is applied to the source line.

At time t4, the read voltage AR is applied to the selected word line WL29.

At time t5, the potential of the bit line is measured, causing the sense amplifier circuit 2 to read data in the selected cell MC29, which completes the data reading. It is desirable that the read voltage AR should have been charged to the maximum voltage by time t5 when the data starts to be read.

As described above, in the embodiment, control is performed so as to cause the inclination θVR of the rising of the read pass voltage VREAD and the inclination θVRK of the rising of the voltage VREADK to be smaller than the inclination θVSG of the select voltage (θVR, θVRK<θVSG) in comparison with a comparative example shown by a broken line. Therefore, as compared with the comparative example (when the inclination of the rising of each of the read pass voltage VREAD and voltage VREADK is θVSG), an area of read voltage VREAD∴time and an area of voltage VREADK×time can be reduced, enabling a read stress to be decreased, which is helpful in reducing read disturbances. This will be described in detail.

2-3. Inclination of the Rising of a Voltage

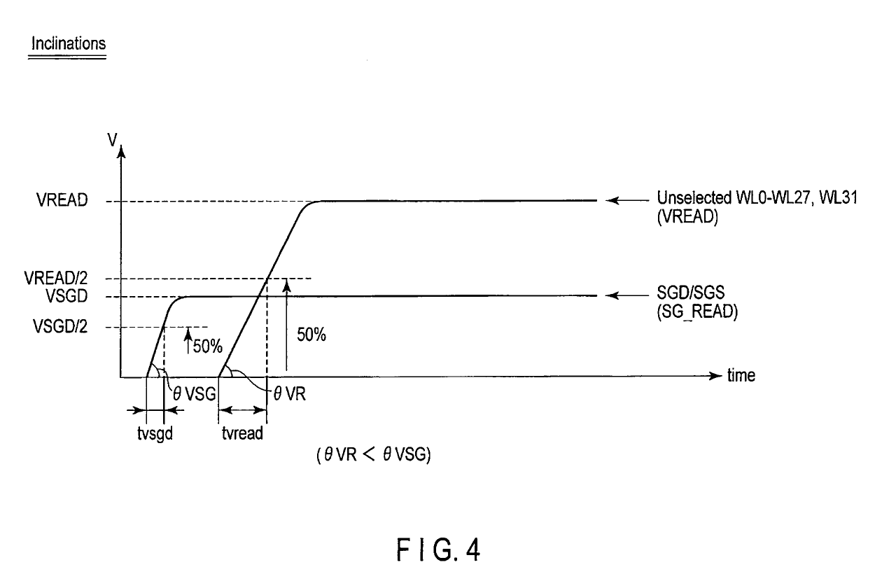

Next, the inclination of the rising of a voltage in the embodiment will be explained with reference to FIG. 4.

As shown in FIG. 4, the inclination θVR of the read pass voltage VREAD, the inclination θVRK of the voltage VREADK, and the inclination θVSG of the select voltage VSG are defined as follows:

The inclination of the rising of a voltage: the time required to reach 50% of the maximum voltage

Specifically, what are shown in FIG. 4 are as follows:

The inclination θVR of read pass voltage VREAD: (VREAD/2)/tvread

The inclination θVSG of select voltage VSG: (VSGD/2)/tvsgd

In the embodiment, the inclination θVRK of voltage VREADK is defined in the same manner as θVR and is almost equal to θVR.

As described above, control is performed so as to cause the inclination θVR of read pass voltage VREAD and the inclination θVRK of voltage READK to be smaller than the inclination θVSG of the select voltage (θVR, θVRK<θVSG). In addition, the read pass voltage VREAD and voltage READK are raised later than the select voltage VSG.

2-4. Generation of Inclinations θVR, θVRK

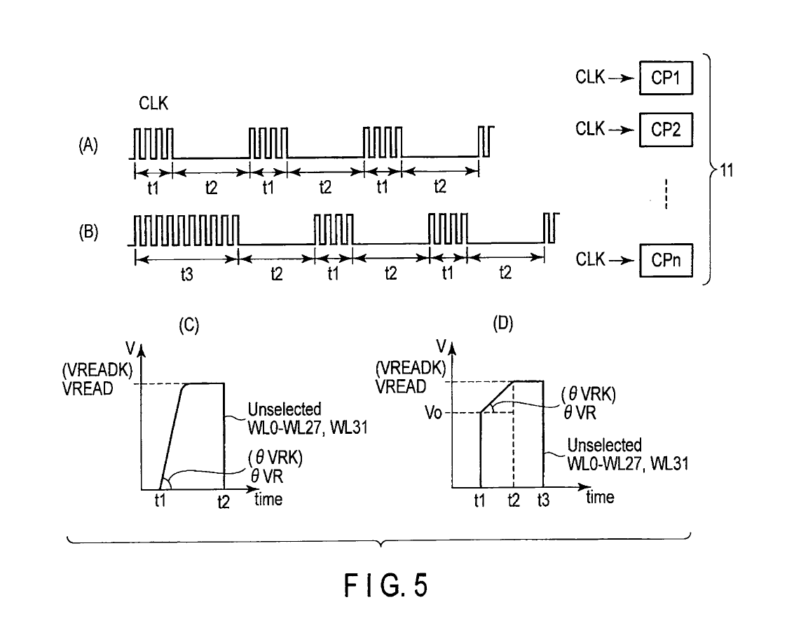

Next, the generation of the inclination θVR of read pass voltage VREAD and the inclination θVRK of voltage VREADK according to the embodiment will be explained with reference to FIG. 5.

First, to obtain an output waveform (C) in FIG. 5, clock pulses CLK to be input to the charge pump circuits (CP1 to CPn) 11 are generated consecutively during period t1-C as shown in clock waveform(A) of FIG. 5, causing the charge pump circuits 11 to operate to continue a step-up operation.

Then, during period t2-C, clock pulses CLK to be input to the charge pump circuits (CP1 to CPn) 11 are stopped, causing the step-up operation to stop.

From the beginning of the rising of the voltage VREAD (VREADK), the step-up operation is repeated during periods t1-C and t2-C until a voltage VREAD is obtained. As a result, a blunt waveform whose rising has an inclination of θVR shown by the output waveform (C) can be generated on the unselected word lines WL0 to WL27 and WL31. In the embodiment, the number of clocks during period t1-C is made smaller (or the frequency of clock is made lower) than the number of clocks in the clock CLK in generating the select voltage VSG so as to cause the inclination θVR to be smaller than the inclination θVSG of the select voltage VSG (θVR<θVSG) until the read pass voltage VREAD to be applied to the unselected word lines WL0 to WL27 and WL31 has been reached. Shortening the time of the clock only during the first period t1-C enables the inclination θVR to be made smaller than the inclination θVSG of the select voltage VSG. The same holds true for the unselected word lines WL28, WL30 adjacent to the selected word line. The aforementioned operations are repeated similarly until the voltage VREADK has been obtained, which makes it possible to generate a blunt waveform whose rising has an inclination of θVRK shown by the output waveform (C).

By doing this, a blunt waveform which rises almost vertically and then inclines at θVR until voltage value VREADK has been reached can be generated on the unselected word lines WL0 to WL27 and WL31. In the embodiment, the number of clocks during period t1 is made smaller than the number of clocks in generating the select voltage VSG so as to cause the inclination θVR to be smaller than the inclination θVSG of the select voltage VSG (θVR<θVSG) until the read pass voltage VREAD to be applied to the unselected word lines WL0 to WL27 and WL31 has been reached. The same holds true for the unselected word lines WL28, WL30 adjacent to the selected word line. The aforementioned operation is carried out similarly, which makes it possible to generate a blunt waveform whose rising has an inclination of θVRK shown by the output waveform (C).

As described above, in the embodiment, the number of clocks in the clock CLK is changed without decreasing the number of charge pump circuits 11, making it possible to generate a blunt waveform, such as the output waveform (C). Therefore, the output voltages supplied from the charge pump circuits 11 can be prevented from variations in the characteristics of the transistors constituting the charge pump circuits 11 or variations in the characteristics of the transistors that cut off by changing the number of clocks in the clock CLK. As a result, the controllability of the charge pump circuits 11 can be improved and the output waveforms form the charge pump circuits 11 can be stabilized.

As another example, an n number of charge pump circuits 11 are used at the beginning of the rising of the waveform and then the number is decreased to n′ (n′<n).

<3. Operational Advantage>

The semiconductor memory device of the first embodiment produces at least the effects described in items (1) and (2).

(1) Read stress can be decreased, which is helpful in reducing read disturbance.

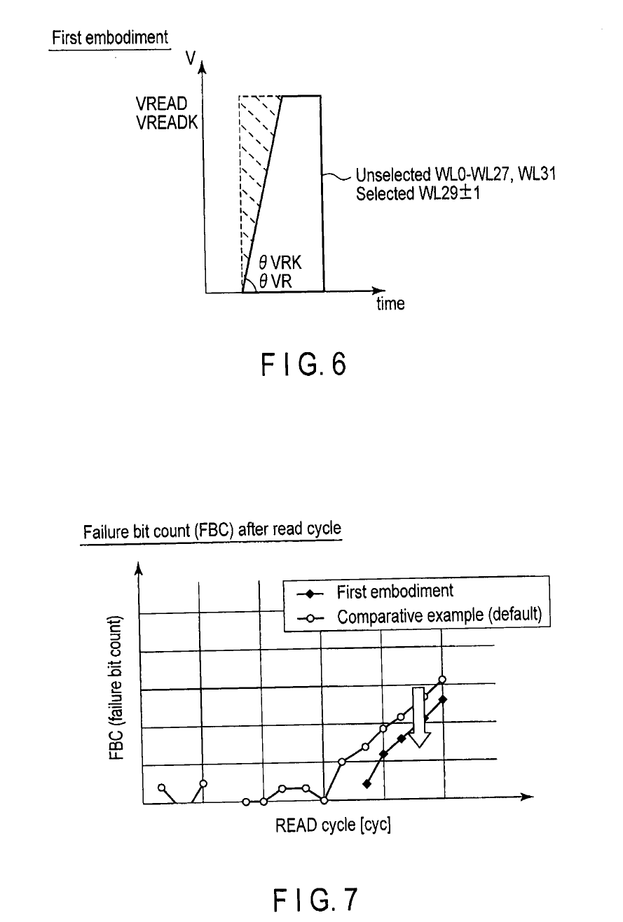

As shown in FIG. 6, in the semiconductor memory device of the first embodiment, the controller (control circuit) 4 performs control so as to cause the inclinations θVR, θVRK to be smaller than the inclination θVSG until the select voltage VSG has been reached (θVR, θVRK<θVSG) until the read pass voltages VREAD, VREADK to be applied to the unselected word lines WL0 to WL27 and WL31 and unselected word lines WL28 and WL30 have been reached and so as to raise the read pass voltages VREAD, VREADK later than the select voltage VSG (time t1, time t2).

Therefore, the voltages applied to the unselected word lines WL0 to WL27 and WL31 and unselected word lines WL28, WL30 until the read pass voltages VREAD, VREADK have been reached can be raised more gently. Therefore, as compared with a comparison example of rising almost vertically as shown by a broken line in FIG. 6, an area of voltage (VREAD or VREADK)×time can be decreased. As a result, read stress can be reduced, which is helpful in decreasing read disturbances.

For example, a failure bit count (FBC) after a read cycle when the first embodiment has been applied is estimated as shown in FIG. 7.

As shown in FIG. 7, it is seen that the voltages VREAD and VREADK are raised gently at θVR and at θVRK, respectively, the failure bit count (read disturbances) can be decreased as compared with the comparative example (default).

When data is read from a NAND flash memory, a voltage output applied to unselected cells connected to the unselected word lines WL0 to WL27 and WL31 and unselected word lines WL28, WL30 are raised gently. This makes it possible to reduce voltage stress on the unselected word lines WL0 to WL27 and WL31 and unselected word lines WL28 and WL30 in reading data, which enables read disturbances to be alleviated.

This has the advantage of improving the reliability of the entire NAND flash memory 21.

(2) The controllability of voltage waveforms can be improved, enabling the voltage waveforms to be stabilized.

As shown in FIG. 5, in the first embodiment, voltage waveforms on the unselected word lines WL0 to WL27 and WL31 and selected word lines WL28 and WL30 can be generated.

Specifically, in the first embodiment, control of the clock waveform in the charge pump circuit is performed so as to cause the inclinations θVR, θVRK to be smaller than the inclination θVSG of the select voltage VSG until the read pass voltages VREAD, VREADK to be applied to the unselected word lines WL0 to WL27 and WL31 and unselected word lines WL28, WL30 have been reached (θVR, θVRK<θVSG).

As described above, in the first embodiment, the number of clocks in the clock CLK is changed without decreasing the number of step-up circuits 11, making it possible to generate a blunt waveform, such as output waveform (C). Therefore, the output voltages supplied from the charge pump circuits 11 can be prevented from variations in the characteristics of the transistors constituting the charge pump circuits 11 or variations in the characteristics of the transistors that cut off by changing the number of clocks in the clock CLK. As a result, the controllability of the output waveforms (C) can be improved and these waveforms can be stabilized.

Furthermore, even if the inclinations θVR, θVRK are made smaller than the inclination θVSG of the select voltage VSG, the read time does not become longer. It is because the read pass voltages VREAD, VREADK have only to rise by Read start time t5. The time t5 appears after the potential of the selected word line WL29 has been stabilized. Therefore, there is a period of several microseconds between time t2 and time t5. In addition, raising the read pass voltages VREAD, VREADK earlier than time t4 prevents the read voltage AR from becoming unstable due to coupling. That is, decreasing the inclination of the rising of each of the read pass voltages VREAD, VREADK has almost no effect on the read time. Consequently, it is possible to alleviate read disturbances without making the read time longer.

### Second Embodiment

### An Example of Raising Voltages Gently in a Plurality Of Stages

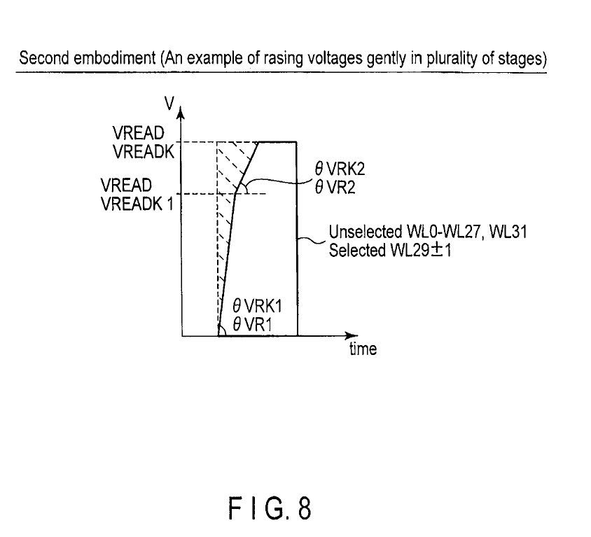

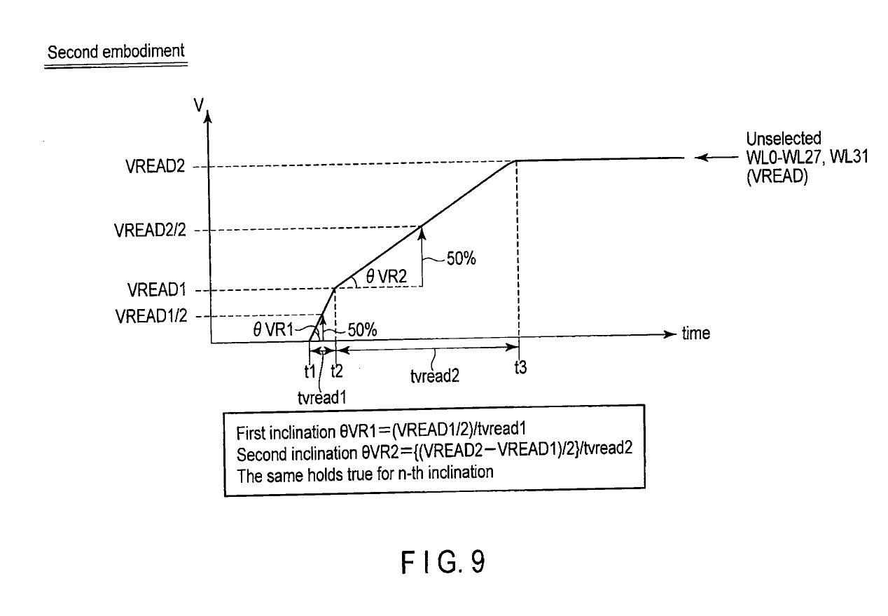

Next, a semiconductor memory device according to a second embodiment will be explained with reference to FIGS. 8 and 9. The second embodiment relates to an example of raising voltages applied to the unselected word lines WL0 to WL27 and WL31 and the unselected word lines WL28 and WL30 gently in a plurality of stages. A detailed explanation of parts overlapping with the first embodiment will be omitted.

First, the second embodiment will be explained briefly with reference to FIG. 8.

As shown in FIG. 8, the second embodiment differs from the first embodiment in that a voltage applied to the unselected word lines WL0 to WL27 and WL31 further has an inclination of θVR2 and a voltage applied to the unselected word lines WL28 and WL30 further has an inclination of θVRK2 and these voltages are raised gently in a plurality of stages. The inclinations θVR2, θVRK2 are controlled so as to be smaller than the inclination θVSG of the select voltage VSG (θVR2, θVRK2<θVSG) and so as to rise in voltage later than the select voltage VSG.

Inclination of the Rising of a Voltage

Next, the inclinations θVR1, θVR2 of the risings of voltages in the second embodiment will be explained with reference to FIG. 9.

As shown in FIG. 9, the inclinations θVR1, θVR2 of the read pass voltage VREAD are defined as follows in the second embodiment:

A first inclination θVR1 of the read pass voltage: (VREAD1/2)/tvread1

A second inclination θVR2 of the read pass voltage: {(VREAD2−VREAD1)/2)/tvread2

While in the second embodiment, the inclination has been changed twice, the inclination of the read pass voltage may be changed in three or more stages (or n times) similarly.

The same holds true for the inclinations θVRK1, θVRK2 of the voltage VREADK.

As for a concrete example of generating voltage waveforms on the unselected word lines WL0 to WL27 and WL31 and unselected word lines WL28 and WL30, voltage waveforms can be generated similarly as shown in FIG. 5.

The remaining configuration and operations are basically the same as those of the first embodiment and therefore a detailed explanation of them will be omitted.

The generation of the inclinations of θVR, θVRK of the read pass voltage VREAD and voltage VREADK respectively will be explained with reference to (B) and (D) in FIG. 5. To obtain a output waveform (D), clock pulses CLK are generated consecutively during a period of t3-C (t3-C>t1-C) until a specific voltage V0 has been reached, causing a voltage to rise almost vertically as shown a clock waveform (B). After the specific voltage V0 has been reached, a period of t1-C and a period of t2-C are repeated until the voltage VEAD has been obtained as in the clock waveform (A).

<Operational Advantage>

As described above, the semiconductor memory device of the second embodiment produces at least the same effects as in item (1) and item (2). In addition, the second embodiment further produces an effect described in item (3).

(3) The controllability of voltage waveforms can be further improved and a read stress and read disturbances can be reduced more stably.

The second embodiment differs from the first embodiment in that voltages applied to the unselected word lines WL0 to WL27 and WL31 and unselected word lines WL28 and WL30 further have inclinations of θVR2, θVRK2 respectively and the voltages are raised gently in a plurality of stages. The inclinations θVR2, θVRK2 are controlled so as to be smaller than the inclination θVSG of the select voltage VSG (θVR2, θVRK2<θVSG) and so as to rise in voltage later than the select voltage VSG.

As described above, raising the voltages gently in plural stages enables the controllability of voltage waveforms to be improved further, which offers the advantage of reducing a read stress and read disturbances more stably.

### Third Embodiment

### An Example of Applying the First and Second Embodiments to VPASS

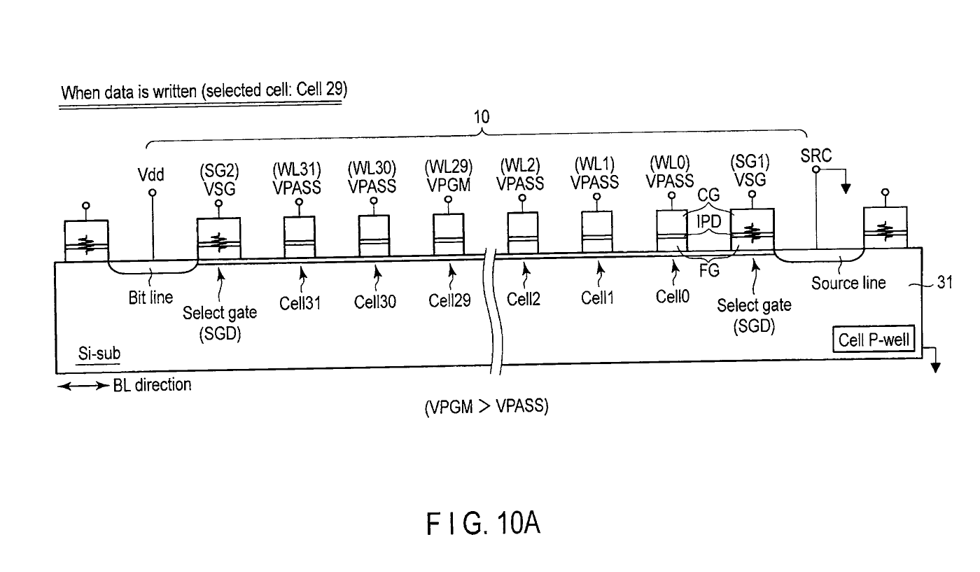

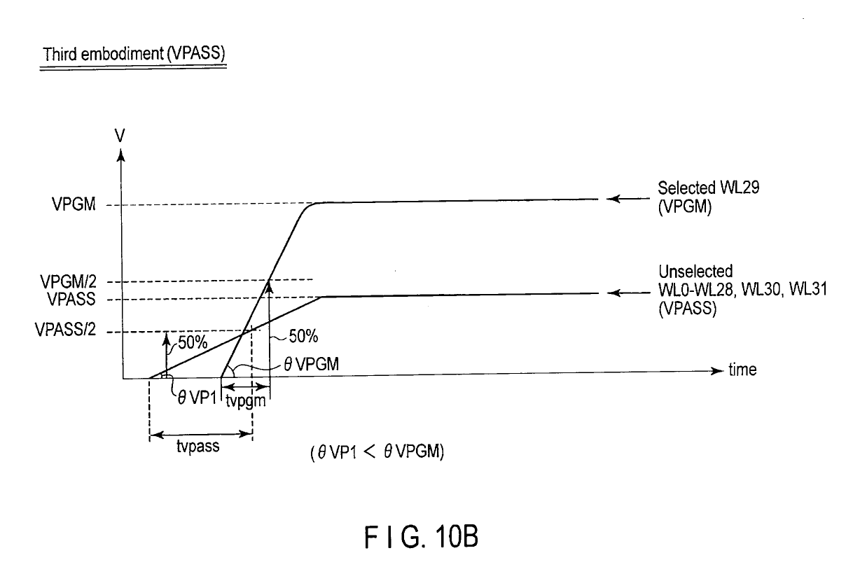

Next, a semiconductor memory device according to a third embodiment will be explained with reference to FIGS. 10A and 10B. The third embodiment relates to an example of applying the first and second embodiments to a write pass voltage VPASS applied to the unselected word lines in a data write operation. A detailed explanation of parts overlapping with the first and second embodiments will be omitted.

The third embodiment will be explained with reference to FIG. 10A.

FIG. 10A shows voltage relations when data is written into a NAND cell unit 10. As shown in FIG. 10A, each of memory cells MC0 to MC31 and select gates SGS, SGD comprises a tunnel insulating film, a charge storage layer (floating electrode) FG, an inter-gate insulating film IPD, and a control gate CG which are provided sequentially on a well of the semiconductor substrate. An opening is made in the central part of the inter-gate insulating film IPD of each of the select gates SGS, SGD, thereby causing the floating electrode FG and control electrode CG to be electrically connected to each other.

With this configuration, the voltage relations in a data write operation are as follows. Suppose the selected cell is memory cell MC29.

A write voltage VPGM is applied to the selected word line WL29 connected to the selected cell MC29.

A write pass voltage VPASS is applied to unselected word lines WL0 to WL28 and WL30 and WL31 of the unselected cells MC0 to MC28 and MC30 and MC31. The write pass voltage VPASS is applied, forming the channels of the unselected cells MC0 to MC28 and MC30 and MC31, which causes a current path to conduct. The write pass voltage VPGM is higher than the write pass voltage VPASS (VPG>VPASS).

A select voltage VSG is applied to select gates SGS, SGD.

When the selected cell is to be written into, for example, the ground potential Vss is applied to the bit line. When the selected cell is not to be written into, for example, an internal power supply voltage Vdd is applied to the bit line.

A source voltage SRC is applied to a source line.

A specific well voltage is applied to a well (Cell P-well) in the semiconductor substrate.

As in the third embodiment, the first and second embodiments may be applied not only to the data read operation but also to a write pass voltage VPASS applied to the unselected word lines in a data read operation.

As shown in FIG. 10B, the inclination of the rising of a voltage in the third embodiment is the same as in the first and second embodiments as described below. An inclination of θVP1 of a write pass voltage VPASS and an inclination of θVPGM of a write voltage VPGM are defined in the third embodiment as follows:

The inclination of the rising of a voltage: the time required to reach 50% of the maximum voltage

More specifically, what are shown in FIG. 10B are as follows:

The inclination θVP1 of write pass voltage VPASS: (VPASS1/2)/tvpass

The inclination θVPGM of write voltage VPGM: (VPGM/2)/tvpgm

As described above, in the third embodiment, control is performed so as to cause the inclination θVP1 of the rising of a write pass voltage VPASS1 to be smaller than the inclination θVPGM of the rising of a write voltage (θVP1<θVPGM). In addition, the write pass voltage VPASS starts to be raised earlier than or almost at the same time as the write voltage VPGM.

<Operational Advantage>

The semiconductor memory device of the third embodiment produces the same effects as described in item (2).

Furthermore, the area of voltage (VPASS)×time can be decreased by performing control so as to cause the inclination θVP1 of the rising of the write pass voltage VPASS1 to be smaller than the inclination θVPGM of the rising of the write voltage (θVP1<θVPGM). As a result, a write stress on the unselected cells can be reduced, which is helpful in reducing write failures.

In this way, the third embodiment may be applied to the write pass voltage VPASS applied to the unselected word lines in a data write operation.

### Fourth Embodiment

### Another Example of Applying the First and Second Embodiments to VPASS

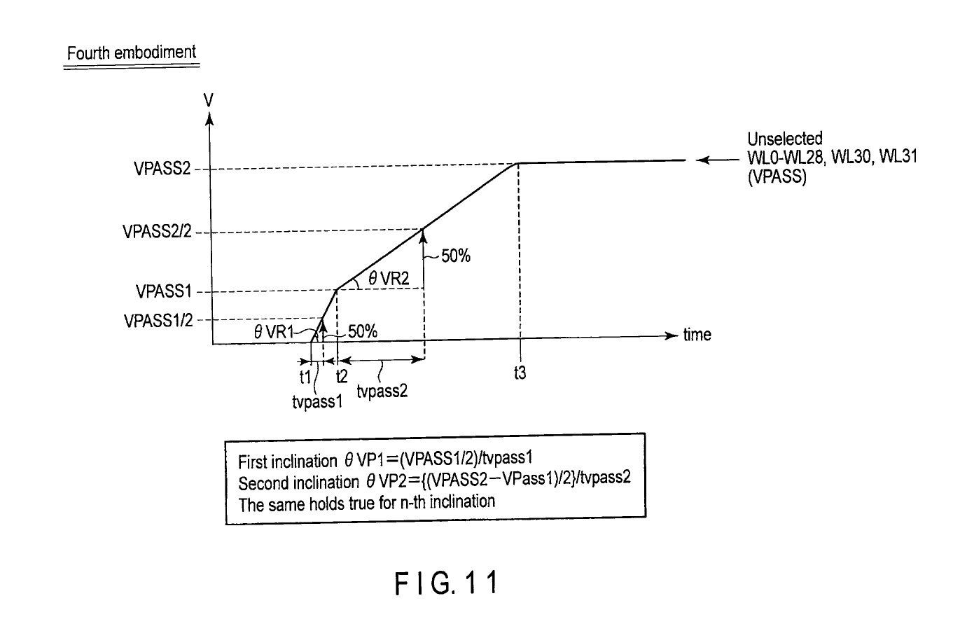

Next, a semiconductor memory device according to a fourth embodiment will be explained with reference to FIG. 11. The fourth embodiment relates to an example of applying the third embodiment to a write pass voltage VPASS applied to the unselected word lines in a data write operation. A detailed explanation of parts overlapping with the third embodiment will be omitted.

The fourth embodiment will be explained with reference to FIG. 11.

As shown in FIG. 11, the fourth embodiment differs from the third embodiment in that a write pass voltage VPASS has an inclination θVP2 of a second rising.

The inclination θVP2 of a second rising is defined as follows in the fourth embodiment.

The inclination θVP2 of a second rising of the write pass voltage: {(VPASS2−VPASS1)/2}/tvpass2

While in the fourth embodiment, the inclination has been changed twice, the inclination of the write pass voltage may be changed in three or more stages (n times) similarly.

A concrete example of generating voltage waveforms on the unselected word lines WL0 to WL28 and WL30 and WL31 is achieved with the configuration of FIG. 5 as described below.

The inclination θVP2 of the rising of the write pass voltage VPASS2 is generated as explained with reference to (D) in FIG. 5. The output waveform (D) for example, is obtained by using the clock waveform (B).

By doing this, it is possible to generate the inclination θVP2 of the rising of the write pass voltage VPASS2 smaller than the inclination θVPGM of the rising of the write voltage VPGM.

<Operational Advantage>

The semiconductor memory device of the fourth embodiment produces the same effects as those of the third embodiment. In addition, the fourth embodiment further produces an effect described in item (3). In addition, it can further produce the inclinations of the rising in a plurality of stages.

### Fifth Embodiment

### An Example of Raising a Voltage Stepwise

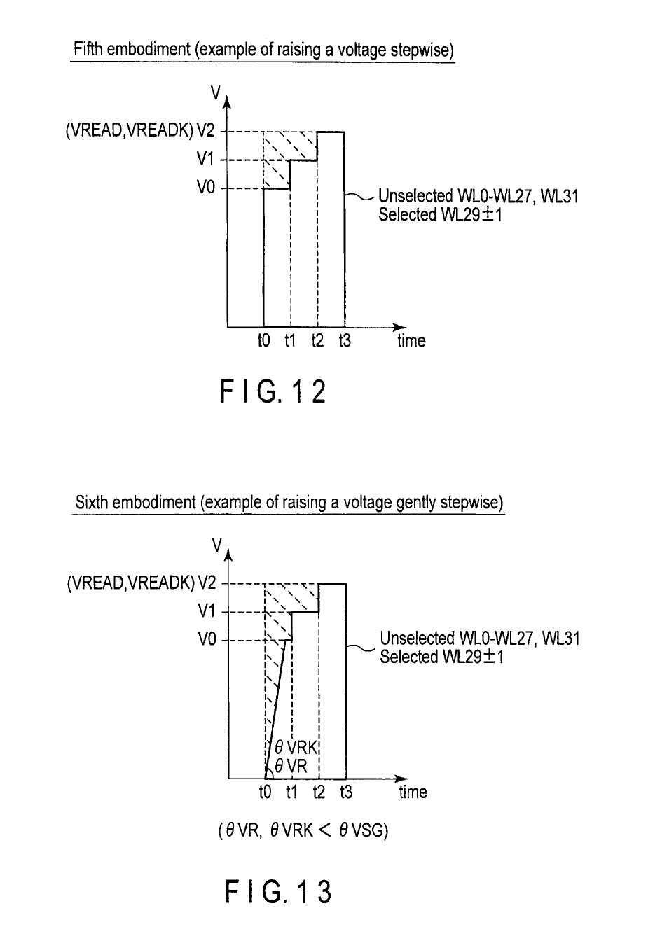

Next, a semiconductor memory device according to a fifth embodiment will be explained with reference to FIG. 12. The fifth embodiment relates to an example of raising stepwise voltages applied to the unselected word lines WL0 to WL27 and WL31 and unselected word lines WL28 and WL30. A detailed explanation of parts overlapping with the first embodiment will be omitted.

The fifth embodiment will be explained with reference to FIG. 12.

As shown in FIG. 12, the fifth embodiment differs from the first embodiment in that voltages applied to the unselected word lines WL0 to WL27 and WL31 and unselected word lines WL28 and WL30 are raised stepwise. Control is performed so as to raise the voltages later than the select voltage VSG.

First, at time t0, a voltage is raised steeply so as to rise almost vertically on unselected word lines WL0 to WL27 and WL31 and the unselected word lines WL28 and WL30 by inputting clock pulses CLK consecutively to the charge pump circuits 11 until voltage V0 has been reached as shown by the clock waveform (B) in FIG. 5.

Then, at time t1, the number of clocks is decreased to the extent that voltage V0 is maintained, after voltage V0 has been reached.

These operations are repeated until the read pass voltages VREAD, VREADK have been reached. By doing this, the voltage waveforms can be raised stepwise as shown in FIG. 12. The fifth embodiment may be applied to the third and fourth embodiments in terms of a write pass voltage VPASS.

<Operational Advantage>

The semiconductor memory device of the fifth embodiment produces the same effects as those described in item (1) to item (3). In addition, the fifth embodiment may be applied.

### Sixth Embodiment

### An Example of Gently Raising a Voltage Stepwise

Next, a semiconductor memory device according to a sixth embodiment will be explained with reference to FIG. 13. The sixth embodiment relates to an example of gently raising stepwise voltages applied to the unselected word lines WL0 to WL27 and WL31 and unselected word lines WL28 and WL30. A detailed explanation of parts overlapping with the first embodiment will be omitted.

The sixth embodiment will be explained with reference to FIG. 13.

As shown in FIG. 13, the fifth embodiment differs from the first embodiment in that a voltage applied to the unselected word lines WL0 to WL27 and WL31 has an inclination of θVR of its rising and a voltage applied to the unselected word lines WL28 and WL30 has an inclination of θVRK of its rising and that the voltages are raised stepwise. Control is performed so as to cause the inclinations θVR, θVRK to be smaller than the inclination θVSG of the select voltage VSG (θVR, θVRK<θVSG) and so as to raise the voltages later than the select voltage VSG.

A concrete example of the inclinations θVR, θVRK of voltage waveforms and of raising the voltages stepwise is the same as described above. The sixth embodiment may be applied to the third and fourth embodiments in terms of a write pass voltage VPASS.

<Operational Advantage>

The semiconductor memory device of the sixth embodiment produces the same effects as those described in item (1) to item (3). In addition, the sixth embodiment may be applied as needed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array comprising a plurality of cell units each composed of a plurality of memory cells which are arranged at intersections of a plurality of bit lines and a plurality of word lines and whose current paths are connected in series and select transistors each connected to either end of the series connection;
a voltage generator circuit which generates a voltage applied to the memory cell array; and
a control circuit which controls the memory cell array and the voltage generator circuit and which, when reading data from a memory cell, performs control so as to cause a rising of a first read pass voltage applied to unselected word lines in the cell units having a first inclination and a rising of a select voltage applied to the select transistor having a second inclination and so as to raise the first read pass voltage later than the select voltage, and the first inclination smaller than the second inclination.

2. The semiconductor memory device of claim 1, wherein the control circuit further performs control so as to cause a rising of a second read pass voltage applied to unselected word line adjacent to a selected word line in the cell unit having a third inclination smaller than the second inclination and so as to raise the unselected word lines adjacent to the select word line in voltage later than the select voltage.

3. The semiconductor memory device of claim 1, wherein the control circuit further performs control so at to cause the first read pass having a plurality of inclinations smaller than the second inclination until a voltage applied to unselected word lines has been reached the first read pass voltage.

4. The semiconductor memory device of claim 2, wherein the control circuit further performs control so as to cause the second read pass voltage having a plurality of inclinations smaller than the second inclination until a voltage applied to unselected word line adjacent to the selected word line has been reached the third read pass voltage.

5. The semiconductor memory device of claim 2, wherein the control circuit further performs control so as to raise stepwise voltages until the voltages have reached the first and second read pass voltages.

6. The semiconductor memory device of claim 2, wherein the voltage generator circuit comprises a step-up circuit to which a clock pulse is input and a pulse generator circuit that generates the clock pulse, and
the control circuit, when reading data from the memory cells, controls the voltage generator circuit so as to make smaller the number of clock pulses in generating the first and second read pass voltages than the number of clock pulses in the clock in generating the select voltage so as to make smaller the first and third inclinations than the second inclination.

7. A method of controlling a semiconductor memory device comprising:
in a data read operation of a memory cell array comprising a plurality of cell units each composed of a plurality of memory cells which are arranged at intersections of a plurality of bit lines and a plurality of word lines and whose current paths are connected in series and select transistors each connected to either end of the series connection,
causing a first voltage applied to unselected word lines in the cell units to have a first inclination until a first read pass voltage has been reached smaller than a second inclination until a select voltage of the select transistor has been reached; and
performing control so as to raise the unselected word line in voltage later than the selected voltage.

8. The method of claim 7, further comprising:
causing a second voltage applied to unselected word lines adjacent to a selected word line in the cell unit to have a third inclination until a second read pass voltage has been reached smaller than the second inclination until the select voltage of the select transistor has been reached; and
performing control so as to raise the unselected word lines adjacent to the select word line in voltage later than the select voltage.

9. The method of claim 7, further comprising:
performing control so as to cause a voltage applied to unselected word lines in the cell units to have a plurality of inclinations smaller than the second inclination until a select voltage of the select transistor has been reached, until the first read pass voltage has been reached so as to rise in a plurality of stages.

10. The method of claim 8, further comprising:
performing control so as to cause a voltage applied to unselected word lines adjacent to the selected word line in the cell units to have a plurality of inclinations smaller than the second inclination until a select voltage of the select transistor has been reached, until the second read pass voltage has been reached so as to rise in a plurality of stages.

11. The method of claim 8, further comprising:
performing control so as to raise stepwise voltages applied to unselected word lines and unselected word lines adjacent to the selected word line in the cell units until the voltages have reached the first and second read pass voltages.

12. The method of claim 7, wherein the semiconductor memory device further comprises a voltage generator circuit that generates voltages applied to the memory cell array, and
a control circuit that controls the memory cell array and the voltage generator circuit.

13. The method of claim 12, wherein the voltage generator circuit comprises a step-up circuit to which a clock pulse is input and a pulse generator circuit that generates a pulse voltage according to the output of the step-up circuit, and
the control circuit, when reading data from the memory cells, controls the voltage generator circuit so as to make smaller the number of clocks in generating the first and second read pass voltages than the number of clocks pulses in the clock in generating the select voltage so as to make smaller the first and third inclinations of the voltages of the unselected word lines and unselected word lines adjacent to the selected word line than the second inclination of the select voltage.
